(19) United States
(12) Patent Application Publication
(10) Pub. No.: US 2026/0053001 A1
(43) Pub. Date: Feb. 19, 2026

(54) BONDED DIE STRUCTURES WITH IMPROVED DIE POSITIONING AND METHODS FOR FORMING THE SAME

(71) Applicant: Taiwan Semiconductor Manufacturing Company Limited, Hsinchu (TW)

(72) Inventors: Jen-Yuan Chang, Hsinchu City (TW); Chi-Yen Lin, Tainan City (TW)

(21) Appl. No.: 18/804,302

(22) Filed: Aug. 14, 2024

(51) Int. Cl. H01L 23/544; H01L 21/56; H01L 23/00; H01L 23/31; H01L 25/065

(52) U.S. Cl. CPC H01L 23/544; H01L 21/561; H01L 23/3121; H01L 23/3135; H01L 24/08; H01L 24/80; H01L 24/94; H01L 25/0657; H01L 2223/54426; H01L 2223/54453; H01L 2224/08145; H01L 2224/80006; H01L 2224/8013; H01L 2224/80895; H01L 2224/80896; H01L 2224/94; H01L 2225/06593; H01L 2924/3512

(57) ABSTRACT

Bonded die structures and methods of fabricating bonded die structures including improved positioning of the dies used to form the structures. Improved positioning may be achieved by providing non-linear alignment features around the periphery of the dies that may facilitate accurate positioning of the dies with respect to one or more alignment marks on the target structures on which the dies are placed. The non-linear alignment features may include features formed in the peripheral edges of the dies, such as indent portions extending inwardly from the peripheral edges of the dies and/or outward bulge portions extending outwardly from the peripheral edges of the dies. Alternatively, or in addition, the non-linear alignment features may be features formed in a seal ring structure of the dies. The non-linear alignment features may improve the accuracy of the positioning of the dies relative to alignment mark(s) on the target structures using optical detection systems.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view illustrating a first carrier structure according to various embodiments of the present disclosure.

FIG. 2 is a vertical cross-sectional view illustrating a first die disposed on the front side of the first carrier structure according to various embodiments of the present disclosure.

FIG. 3 is a vertical cross-sectional view illustrating a first dielectric material laterally surrounding the first die and a plurality of second alignment marks formed over the first dielectric material according to an embodiment of the present disclosure.

FIG. 4 is a vertical cross-sectional view illustrating a stacked device structure including a second die disposed the first die and surrounded by a second dielectric material according to various embodiments of the present disclosure.

FIG. 5 is a vertical cross-sectional view of the stacked device structure disposed on a second carrier structure according to various embodiments of the present disclosure.

FIG. 6 is a vertical cross-sectional view of a bonded die structure according to various embodiments of the present disclosure.

FIG. 7 is a vertical cross-sectional view showing the bonded die structure mounted on a support structure via a plurality of solder balls according to various embodiments of the present disclosure.

FIG. 8A is a top view of a first die disposed on a first carrier structure according to various embodiments of the present disclosure.

FIG. 8B is an enlarged view of region B of FIG. 8A.

FIG. 8C is a vertical cross-sectional view of a portion of the first carrier structure and the first die taken along line C-C′ in FIG. 8A.

FIG. 8D is a vertical cross-sectional view of a portion of the first carrier structure and a first alignment mark taken along line D-D′ in FIG. 8A.

FIG. 9 is a top view of a portion of a first die disposed on a first carrier structure according to another embodiment of the present disclosure.

FIG. 10 is a top view of a portion of a first die disposed on a first carrier structure according to another embodiment of the present disclosure.

FIG. 11 is a top view of a portion of a first die disposed on a first carrier structure according to another embodiment of the present disclosure.

FIG. 12 is a top view of a portion of a first die disposed on a first carrier structure according to another embodiment of the present disclosure.

FIG. 13 is a top view of a portion of a first die disposed on a first carrier structure according to another embodiment of the present disclosure.

FIG. 14A is a top view of a portion of a first die disposed on a first carrier structure including outward bulge portions that extend outwardly from the respective side portions of the peripheral edge of the first die according to another embodiment of the present disclosure.

FIG. 14B is a top view of a portion of a first die disposed on a first carrier structure 100 according to another embodiment of the present disclosure.

FIG. 14C is a top view of a portion of a first die disposed on a first carrier structure including outward bulge portions that partially overlap the corresponding first alignment marks according to an embodiment of the present disclosure.

FIG. 14D is a top view of a portion of a first die disposed on a first carrier structure including outward bulge portions having triangular shapes that partially overlap the corresponding first alignment marks according to another embodiment of the present disclosure.

FIGS. 15A-15C are top views of a portion of a first die disposed on a first carrier structure in accordance with various additional embodiments of the present disclosure.

FIGS. 16A-16E are top views of a portion of a first die disposed on a first carrier structure illustrating various configurations of non-linear alignment features in the peripheral edge of the first die and first alignment marks in accordance with various embodiments of the present disclosure.

FIGS. 17A and 17B are top views of a portion of a first die disposed on a first carrier structure illustrating discontinuous second seal ring segments having non-linear alignment features in accordance with various embodiments of the present disclosure.

FIG. 18 is a flowchart illustrating a method of fabricating a bonded die structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures.

The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices and methods of fabrication thereof. Specifically, various embodiments include semiconductor device structures including semiconductor integrated circuit (IC) dies having non-linear alignment features on or adjacent to the edges of the semiconductor IC dies to enable improved precision in the alignment and stacking of multiple device structures.

Semiconductor integrated circuits may include a semiconductor material substrate, such as a silicon substrate, having a number of circuit components and elements formed on and/or within the semiconductor material. Semiconductor integrated circuits are typically fabricated by sequentially depositing insulating or dielectric layers, conductive layers, and semiconductive layers of material over the semiconductor substrate (e.g., a wafer), and patterning the various material layers using lithography to form integrated circuits. Portions of the semiconductor substrate containing separate integrated circuits thereon may then be separated (i.e., singulated) from the remainder of the semiconductor substrate via a dicing process to provide individual dies.

A bonded die structure may be formed by placing a second die on top of first die and performing a bonding process to bond bonding features on the first die to corresponding bonding features on the second die. Accurate alignment and positioning of the respective dies is desired because misalignment of the dies can result in poor bond formation and other defects. In many cases, alignment marks are used to facilitate alignment of the respective dies in instances in which they are placed onto another structure, such as a carrier wafer or another die. Alignment marks may include identifiable features, such as geometric shapes or patterns, that may function as a reference or guide as to the precise placement of the dies. An optical detection system is often utilized to measure the position of the die relative to the alignment mark(s) and to correct the positioning of the die when the die is placed improperly with respect to the alignment mark(s).

However, related optical detection systems frequently produce inaccurate measurements of the die position relative to the alignment marks. This can result in improper die placement and thereby lead to poor performance and reduced yields in the resultant bonded die structures.

Various embodiments disclosed herein may include bonded die structures and methods of fabricating bonded die structures that include improved positioning of the dies used to form the bonded die structures. The improved positioning may be achieved by providing one or more non-linear alignment features around the periphery of the dies that may facilitate more accurate positioning of the dies with respect to one or more alignment marks on the target structures on which the dies are placed. In some embodiments, the non-linear alignment features may include features formed in the peripheral edges of the dies, such as indent portions extending inwardly from the peripheral edges of the dies and/or outward bulge portions extending outwardly from the peripheral edges of the dies. Alternatively, or in addition, the non-linear alignment features may be features formed in a seal ring structure of the dies, such as indent portions of the seal ring structure extending inwardly from the peripheral edges of the dies and/or outward bulge portions of the seal ring structure extending outwardly from the peripheral edges of the dies. The non-linear alignment features may improve the accuracy of the positioning of the dies with respect to alignment mark(s) on the target structures using optical detection systems.

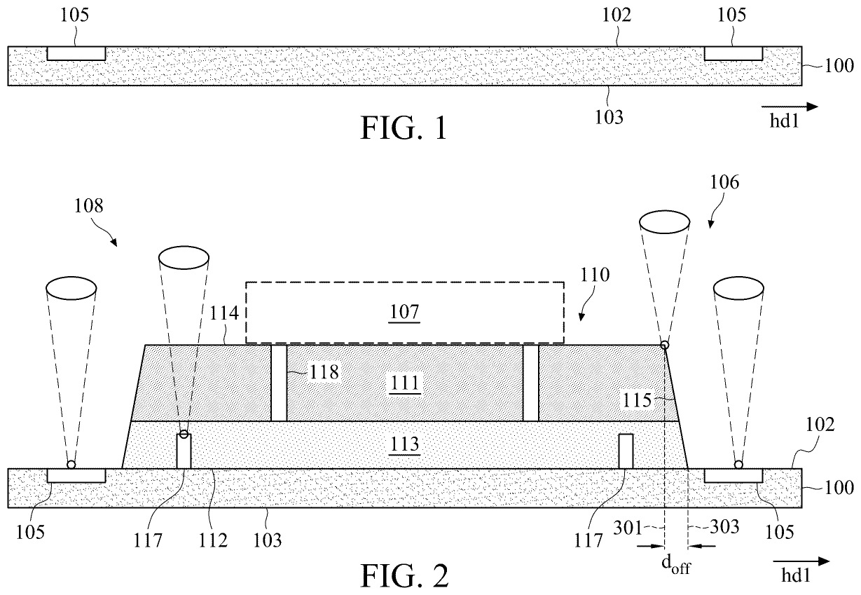

FIGS. 1-7 are sequential vertical cross-sectional views illustrating the intermediate structures during a process of fabricating a semiconductor device structure according to various embodiments of the present disclosure. FIG. 1 is a vertical cross-sectional view illustrating a first carrier structure 100 according to various embodiments of the present disclosure. The first carrier structure 100 may include a suitable substrate (e.g., a semiconductor substrate, an organic substrate, a glass substrate, a ceramic substrate, etc.) that may be configured to support one or more semiconductor IC dies. In one non-limiting embodiment, the first carrier structure 100 may include a semiconductor (e.g., silicon) wafer. The first carrier structure 100 may include a first (i.e., front) side 102 and a second (i.e., back) side 103. In various embodiments, the first carrier structure 100 may include a plurality of first alignment marks 105 disposed on and/or within the first carrier structure 100. The first alignment marks 105 may include discreate features (e.g., geometric shape(s)) that may be detectable visually and/or via the use of an optical detection system as described in further detail below. The first alignment marks 105 may be used to facilitate precise alignment of structures, such as semiconductor IC dies, that are subsequently placed on the front side 102 of the first carrier structure 100.

In some embodiments, the first alignment marks 105 may include a suitable metallic material, such as Cu, Ni, W, Al, Co, Mo, Ru, Ti, TiN, TaN, or WN, including alloys and combinations of the same. Other suitable materials and configurations for the first alignment marks 105, such as polymers, inks, void areas (e.g., trenches), etc., are within the contemplated scope of disclosure. In some embodiments, the first alignment marks 105 may be formed using photolithographic processes. For example, a metallic material may be deposited over the front side 102 of the first carrier structure 100 using a suitable deposition method. A photoresist layer may be applied over the metallic material and patterned using photolithographic techniques to provide a mask in the pattern of the first alignment marks 105. An etching process may be used to remove portions of the metallic material exposed through the mask and thereby transfer the mask pattern to the metallic material to form discrete first alignment marks 105. In other embodiments, a photoresist mask may be provided over the front side 102 of the first carrier structure 100 and an etching process may be used to form openings (e.g., trenches) in the pattern of the first alignment marks 105 in the first carrier structure 100. A metallic material may then be deposited over the front side 102 of the first carrier structure 100 and within the openings. A planarization process may be used to remove excess metallic material from over the front side 102 of the first carrier structure 100 to provide discrete first alignment marks 105 composed of the metallic material deposited within the first carrier structure 100. Other methods for forming the first alignment marks 105, such as lift-off techniques, printing methods, etc., may also be utilized. In some cases, the first alignment marks 105 may be fully embedded within the first carrier structure 100 such that they are covered by an optically transparent material.

FIG. 2 is a vertical cross-sectional view illustrating a first die 110 disposed on the front side 102 of the first carrier structure 100 according to various embodiments of the present disclosure. Referring to FIG. 2, the first die 110 may include a first semiconductor substrate 111 that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 111 may be a semiconductor-on-insulator (SOI) substrate. In some embodiments, a plurality of devices (not shown in FIG. 2) may be disposed on, over and/or in the first semiconductor substrate 111. The devices may include, for example, active devices, passive devices, or a combination thereof. In some embodiments, the devices disposed on, over and/or in the first semiconductor substrate 111 may include integrated circuit devices. The integrated circuit devices may include, for example, transistors (e.g., field-effect transistors (FETs), capacitors, resistors, diodes, photodiodes, fuse devices, or other similar devices. In some embodiments, the integrated circuit devices may include gate electrodes, source/drain regions, spacers, isolation trenches, and the like.

The first die may additionally include a first interconnect structure 113 over the first semiconductor substrate 111. The first interconnect structure 113 may include metal interconnect features (e.g., metal lines, vias and/or bonding pads) formed within a dielectric material (e.g., one or more inter-layer dielectric (ILD) layers and/or inter-metal dielectric (IMD) layers) that may provide connections to and/or between various devices located on, over and/or in the first semiconductor substrate 111. The first interconnect structure 113 may optionally also include one or more first seal rings 117 that may extend around the periphery of the first die 110. The one or more first seal rings 117 may provide protection to the device structures of the first die 110 against electrical interference, mechanical damage and/or contamination. In some embodiments, the one or more first seal rings 117 may include a metallic material (e.g., copper, nickel, aluminum, etc.). In some embodiments, the first die 110 may also include one or more first through-substrate vias (TSVs) 118 extending through the first semiconductor substrate 111. The first TSVs 118 may provide electrical connections through the first semiconductor substrate 111 to the device structures and/or metal features of the first interconnect structure 113 of the first die 110.

Referring again to FIG. 2, the first die 110 may be placed onto the front side 102 of the first carrier structure 100 using a suitable placement apparatus, such as a pick-and-place tool 107. One or more first alignment marks 105 may be utilized as a guide to help ensure that the first die 110 is placed in the correct location on the first carrier structure 100. In various embodiments, one or more optical detection systems may be utilized to compare the position of the first alignment mark(s) 105 with the first die 110 to determine whether the first die 110 is properly located on the first carrier structure 100. In some embodiments, an optical metrology (OM) system 106 may be utilized to perform an overlap measurement between the first alignment mark(s) 105 and one or more peripheral edge(s) 115 of the first die 110 and may be configured to cause the pick-and-place tool 107 to perform one or more process corrections based on the overlap measurement value(s) until it is determined that the first die 110 is properly situated on the first carrier structure 100. Alternatively, or in addition, an infrared (IR) inspection system 108 may be used to detect the offset value between the first alignment mark(s) 105 and a feature of the first die 110, such as a metal (e.g., copper) seal ring 117 of the first die 110. The position of the first die 110 on the first carrier structure 100 may be adjusted based on the IR inspection.

In some embodiments, a plurality of first dies 110 may be placed in predetermined locations over the front side 102 of the first carrier structure 100 using the alignment marks 105 to ensure proper alignment and registration of the respective first dies 110. In some embodiments, the first dies 110 may be adhered to the front side 102 of the first carrier structure 100 using a suitable adhesive (not shown in FIG. 2). In some embodiments, the adhesive may include a material that may be subsequently treated to cause the adhesive to lose its adhesive properties, such that the first carrier structure 100 may be separated from the first dies 110. In some embodiments, the adhesive may lose its adhesive properties when subjected to treatment using an energy source, such as a thermal, optical (e.g., UV, IR, laser, etc.) and/or sonic (e.g., ultrasonic) energy source. Alternatively, the adhesive may include a material, such as an acrylic pressure-sensitive adhesive material, that may decompose when subjected to an elevated temperature. Other suitable adhesive materials are within the contemplated scope of disclosure.

In the embodiment shown in FIG. 2, the first die 110 is shown placed onto the front side 102 of the first carrier structure 100 in a “face down” configuration such that a front side 112 of the first die 110 (i.e., the side adjacent to the first interconnect structure 113) faces towards the first carrier structure 100 and a back side 114 of the first die 110 (i.e., the side adjacent to the first semiconductor substrate 111) faces away from the first carrier structure 100. However, it will be understood that in other embodiments, the first die 110 may be placed in a “face up” configuration where the back side 114 of the first die 110 may face towards the first carrier structure 100 and the front side 112 of the first die 110 may face away from the first carrier structure 100.

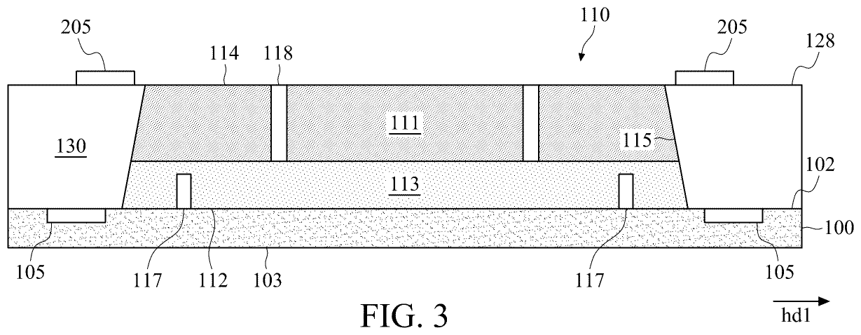

FIG. 3 is a vertical cross-sectional view illustrating a first dielectric material 130 laterally surrounding the first die 110 and a plurality of second alignment marks 205 formed over the first dielectric material 130 according to an embodiment of the present disclosure. Referring to FIG. 3, a first dielectric material 130 may be deposited over the front side 102 of the first carrier structure 100 and the first die 110. The first dielectric material 130 may include a suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), etc., including combinations thereof. Other suitable dielectric materials for the first dielectric material 130 are within the contemplated scope of disclosure. The first dielectric material 130 may be deposited using a suitable deposition process, such as chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like. In some embodiments, the first dielectric material 130 may be deposited over the front side 102 of the first carrier structure 100 and over the first die 110, and a planarization process, such as a chemical mechanical planarization (CMP) process, may be used to remove excess dielectric material from over the first die 110 to provide a first dielectric material 130 laterally surrounding the first die 110. The upper surface of the first dielectric material 130 and the back side 114 of the first die 110 may form a continuous planar surface 128. In embodiments in which multiple first dies 110 are disposed over the front side 102 of the first carrier structure 100, the first dielectric material 130 may extend between each of the first dies 110 and may also be referred to as a first gap fill dielectric material 130.

Referring again to FIG. 3, one or more second alignment marks 205 may be formed over the continuous planar surface 128 formed by the first dielectric material 130 and the first die 110. The one or more second alignment marks 205 may be formed using similar processes and materials as were used to form the first alignment marks 105 described above with reference to FIG. 1. Thus, repeated discussion of like features is omitted for brevity. The second alignment marks 205 may be in known locations with respect to one or more underlying features, such as the first alignment marks 105 and/or the first die(s) 110. The second alignment marks 205 may be used to facilitate alignment of a second die that may be subsequently placed over the first die 110. Although the embodiment of FIG. 3 illustrates the second alignment marks 205 formed over the first dielectric material 130, it will be understood that one or more second alignment marks 205 may be formed over the first die 110 and/or partially over the first dielectric material 130 and partially over the first die 110. Further, although the embodiment of FIG. 3 illustrates the second alignment marks 205 disposed over the continuous planar surface 128, in other embodiments, the second alignment marks may be located at least partially below the continuous planar surface (e.g., partially or fully embedded within the first dielectric material 130 and/or the first die 110).

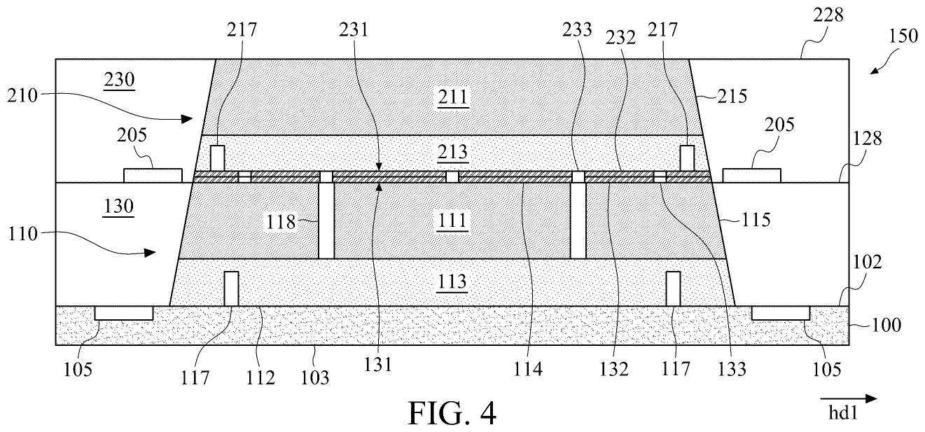

FIG. 4 is a vertical cross-sectional view illustrating a stacked device structure 150 including a second die 210 disposed the first die 110 and surrounded by a second dielectric material 230 according to various embodiments of the present disclosure. Referring to FIG. 4, the second die 210 may be similar to the first die 110 and may include a second semiconductor substrate 211 and a second interconnect structure 213 over the second semiconductor substrate 211, as described above with reference to FIG. 2. Thus, repeated discussion of equivalent features is omitted for brevity. In some embodiments, the second interconnect structure 213 may include at least one second seal ring 217.

The second die 210 may be placed onto first die 110 using a suitable placement apparatus, such as an above-described pick-and-place tool 107. The one or more second alignment marks 205 may help to ensure that the second die 210 is placed in the proper location. One or more optical detection systems, such as an above-described OM system 106 and/or an IR inspection system 108 (see FIG. 2) may be utilized to compare the position of the second die 210 with respect to the second alignment mark(s) 205 to determine that the second die 210 is properly located, and the position of the second die 210 may be adjusted as necessary until it is in the proper location.

Referring again to FIG. 4, in some embodiments, the first die 110 may be bonded to the second die 210 via respective first bonding layer 131 and second bonding layer 231. The first bonding layer 131 may be formed over the back surface 114 of the first die 110 prior to placing the second die 210 onto the first die 110. In various embodiments, the first bonding layer 131 may include a first dielectric layer 132 having first bonding pads 133 formed therein. The first dielectric layer 132 may include silicon oxide, silicon nitride, silicon carbide, silicon carbon nitride, silicon oxynitride, a dielectric polymer material, or the like. Other suitable dielectric materials are within the contemplated scope of disclosure. The first bonding pads 133 may include a suitable conductive material, such as copper (Cu), tungsten (W), aluminum (Al), and the like. The first bonding pads 133 may be formed in the first dielectric layer 132 via a damascene or dual-damascene process, for example. At least some of the first bonding pads 133 of the first bonding layer 131 may be electrically coupled to TSVs 118 of the underlying first semiconductor substrate 111 of the first die 110.

The second bonding layer 231 may be formed in a similar fashion over a side of the second interconnect structure 213 of the second die 210. In particular, the second bonding layer 231 may include a second dielectric layer 232 having second bonding pads 233 formed therein. At least some of the second bonding pads 233 of the second bonding layer 231 may be electrically coupled to metal interconnect features of the second interconnect structure 213 of the second die 210. A layout of the first bonding pads 133 of the first bonding layer 131 may correspond to the layout of the second bonding pads 233 of the second bonding layer 231.

Referring again to FIG. 4, the second die 210 may be placed onto the first die 110 such that the second bonding layer 231 may contact the first bonding layer 131.

The second die 210 may be aligned over the first die 110 such that first bonding pads 133 of the first bonding layer 131 of the first die 110 may be aligned with and contact corresponding second bonding pads 233 of the second bonding layer 231 of the second die 210. Thus, proper positioning of the first die 110 and the second die 210 on the first carrier structure 100 may be desired to ensure a proper amount of contact between corresponding sets of first bonding pads 133 and second bonding pads 233 of the respective first bonding layer 131 and second bonding layer 231. Excessive misalignment or “overlay shift” between the sets of first bonding pads 133 and second bonding pads 233 may result in high electrical resistance across the bonding interface between the first die 110 and the second die 210, which may result in poor device performance and reduced yields. In some cases, a maximum allowable overlay shift between the sets of first bonding pads 133 and second bonding pads 233 may be 1 μm or less.

A bonding process may be utilized to bond the second bonding layer 231 and the first bonding layer 131 and thereby bond the second die 210 to the first die 110. In some embodiments, the second bonding layer 231 may be bonded to the first bonding layer 131 via a metal-to-metal (M-M) and dielectric-to-dielectric (D-D) direct bonding technique to couple the second die 210 mechanically and electrically to the first die 110. In some embodiments, prior to bonding the second die 210 to the first die 110, the surfaces of the first bonding layer 131 on the first die 110 and/or the second bonding layer 231 on the second die 210 may optionally be subjected to a pre-treatment process (e.g., a plasma treatment process) to promote surface activation of the first bonding layer 131 and/or the second bonding layer 231 prior to bonding the second die 210 to the first die 110. In a direct bonding process, such as a metal-to-metal (M-M) and dielectric-to-dielectric (D-D) bonding process, bringing the first bonding layer 131 and the second bonding layer 231 into contact with one another may result in a pre-bonding process in which chemical bonds (e.g., hydrogen bridge bonds) may form at the planar interface between the dielectric material of the first bonding layer 131 and the dielectric material of the second bonding layer 231. In some embodiments, the pre-bonding process may be performed at ambient temperature (e.g., ˜20° C.). In other embodiments, the pre-bonding process may be performed at an elevated temperature. In some embodiments, a compressive force may be applied to the second die 210 and the first die 110 during the pre-bonding process. In other embodiments, no compressive force may be applied during the pre-bonding process.

Referring again to FIG. 4, in some embodiments, an annealing process may be performed to complete the bonding of the bonding pads 133 of the first bonding layer 131 to the bonding pads 233 of the second bonding layer 231 according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the second die 210 and the first die 110 during the annealing process. In other embodiments, no compressive force may be applied during the annealing process.

Following the bonding process, the second die 210 may be mechanically and electrically coupled to the first die 110 to provide a stacked device structure 150 located on the first carrier structure 100. In some embodiments, a plurality of stacked device structures 150 as shown in FIG. 4 may be located over the front side 102 of the first carrier structure 100. In the embodiment of FIG. 4, the stacked device structure 150 includes a configuration in which the front side of the second die 210 (i.e., the side adjacent to the second interconnect structure 213) is bonded to the back side 114 of the first die 110 (i.e., a “front-to-back” configuration). However, it will be understood that other embodiments of the stacked device structure 150 may have a different configuration, such as a “back-to-front” configuration, a “front-to-front” configuration, or a “back-to-back” configuration. Further, although a metal-to-metal (M-M) and dielectric-to-dielectric (D-D) direct bonding process is described herein, it will be understood that other bonding processes, such as a fusion bonding process, a microbump bonding process, etc., may be used to bond the first die 110 and the second die 210.

Referring again to FIG. 4, a second dielectric material 230 may be deposited over the continuous planar surface 128 and the second die 210. The second dielectric material 230 may be similar or identical to the first dielectric material 130 described above with reference to FIG. 3. Thus, repeated discussion of like features is omitted for brevity. In some embodiments, the second dielectric material 230 may be deposited over the continuous planar surface 128 formed by the first dielectric material 130 and the first die 110 and over the side surfaces and upper surface of the second die 210. A planarization process, such as a chemical mechanical planarization (CMP) process, may be used to remove excess dielectric material from over the upper surface of the second die 210 to provide a second dielectric material 230 laterally surrounding the second die 210. The upper surfaces of the second die(s) 210 and the second dielectric material 230 may form a continuous planar surface 228. In embodiments in which multiple second dies 210 are disposed over the continuous planar surface 128, the second dielectric material 230 may extend between each of the second dies 210 and may also be referred to as a second gap fill dielectric material 230.

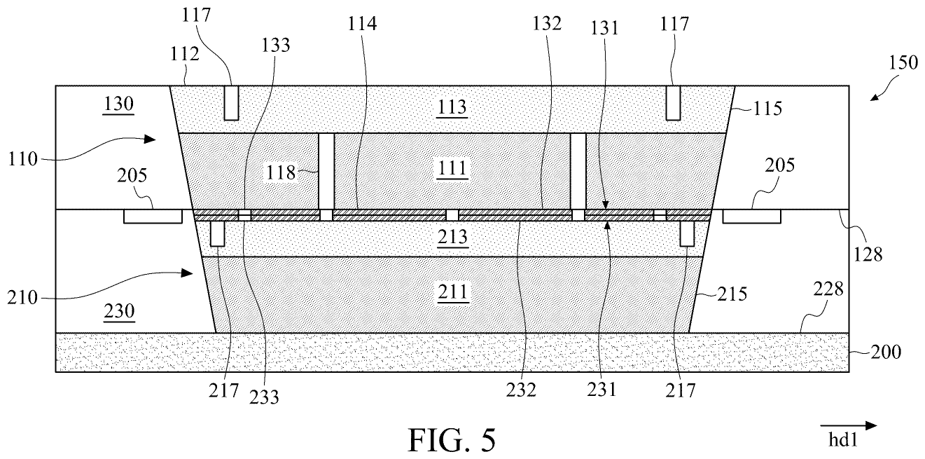

FIG. 5 is a vertical cross-sectional view of the stacked device structure 150 disposed on a second carrier structure 200 according to various embodiments of the present disclosure. Referring to FIG. 5, a second carrier structure 200 may be bonded to the continuous planar surface 228 formed by the second die(s) 210 and the second dielectric material 128. The second carrier structure 200 may include a suitable substrate (e.g., a semiconductor substrate, an organic substrate, a glass substrate, a ceramic substrate, etc.) that may be configured to support the stacked device structure 150. In one non-limiting embodiment, the second carrier structure 200 may include a semiconductor (e.g., silicon) wafer. In various embodiments, the second carrier structure 200 may be bonded to the stacked device structure 150 using a suitable adhesive, such as a glue.

Referring again to FIG. 5, the first carrier structure 100 may be removed from the stacked device structure 150 using a suitable technique. In some embodiments, this may include subjecting an adhesive material that bonds the first carrier structure 100 to the stacked device structure 150 to a treatment, such a thermal treatment, a radiation treatment, etc., that causes the adhesive material to lose its adhesive properties and then separating the first carrier structure 100 from the stacked device structure 150. Other suitable techniques for removing the first carrier structure 100 are within the contemplated scope of disclosure. The first carrier structure 100 may be removed from the stacked device structure 150 either before or after the second carrier structure 200 is attached to the stacked device structure 150. Thus, the stacked device structure 150 may be effectively transferred from the first carrier structure 100 to the second carrier structure 200. The orientation of the stacked device structure 150 may be inverted (i.e., flipped over) relative to the orientation shown in FIG. 4 such that the stacked device structure 150 may be supported on the second carrier structure 200 with the first die 110 located over the second die 210.

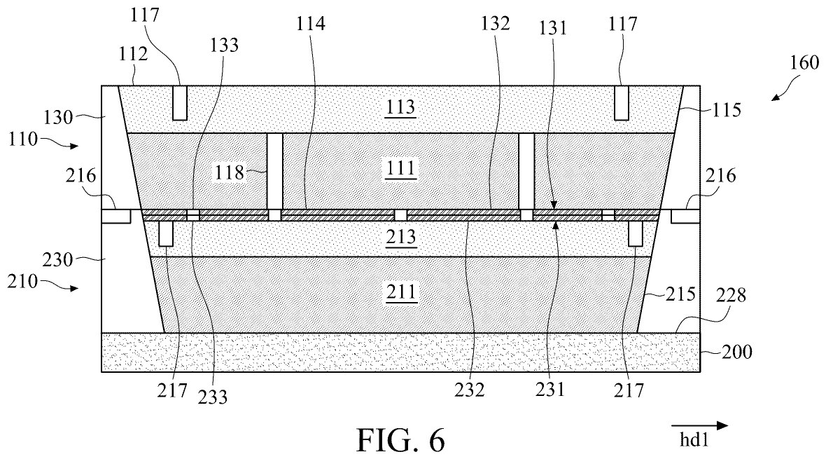

FIG. 6 is a vertical cross-sectional view of a bonded die structure 160 according to various embodiments of the present disclosure. In various embodiments, the structure shown in FIG. 5 may be subjected to a dicing process. The dicing process may include a mechanical dicing process that utilizes a blade, such as a diamond or carbide blade, to cut (e.g., saw) through the gap fill dielectric material 130, 230 and the second carrier structure 200 to provide one or more individual bonded die structures 160 as shown in FIG. 6. Other dicing techniques, such as plasma dicing, laser grooving, etc., may also be utilized. In some embodiments, the second alignment marks 205 may be used as a guide during the dicing process. The bonded die structure 160 may include a second die 210 located over a second carrier structure 200 and a first die 110 located over and bonded to the second die 210. Dielectric material 130, 230 may laterally surround the first die 110 and the second die 210.

In some embodiments, the bonded die structure 160 may include at least one alignment mark structure 216. As used herein, an “alignment mark structure” may include all or any portion of a first alignment mark 105 and/or second alignment mark 205 formed during a process of fabricating a bonded die structure 160 that remains present in the finished bonded die structure 160. For example, an alignment mark structure 216 may be a complete first alignment mark 105 and/or second alignment mark 205, or it may be a portion of first alignment mark 105 and/or second alignment mark 205 that remains present in the bonded die structure 160 following an above-described dicing process. For example, the dicing process may cut through one or more of the first alignment mark 105 and/or second alignment mark 205 such that a portion of one or more of the first alignment mark 105 and/or second alignment mark 205 may remain in the bonded die structure 160 following the dicing process, such as shown in FIG. 6. In other embodiments, an alignment mark structure 216 may include a complete first alignment mark 105 or second alignment mark 205 that is left fully intact in the bonded die structure 160 following the dicing process.

Alternatively, in some embodiments, the dicing may occur between the peripheral edges 115, 215 of the first die 110 and second die 210 and the of the first alignment mark 105 and/or second alignment mark 205, in which case no portions of the of the first alignment mark 105 or second alignment mark 205 may remain in the bonded die structure 160.

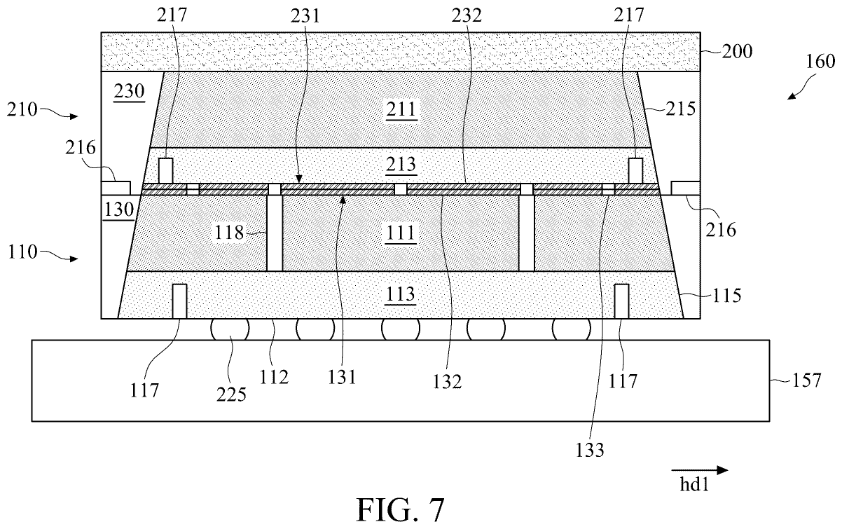

FIG. 7 is a vertical cross-sectional view showing the bonded die structure 160 mounted on a support structure 157 via a plurality of solder balls 225 according to various embodiments of the present disclosure. Referring to FIG. 7, the bonded die structure 160 may be inverted (i.e., flipped over) relative to its orientation as shown in FIG. 6 such that the front side 112 of the first die 110 faces downwards and the back side of the second carrier structure 200 faces upwards. A plurality of solder balls 225 may be provided on the front side 112 of the first die 110. The bonded die structure 160 may be aligned over a support structure 157. The support structure 157 may include, for example, a semiconductor wafer, an interposer, and/or a substrate (e.g., a semiconductor, a glass, or an organic substrate) that may be configured to support the bonded die structure 160. The bonded die structure 160 may be brought into contact with the support structure 157 such that the solder balls 225 may contact corresponding bonding structures (e.g., bonding pads) on the surface of the support structure 157. A reflow process may be used to bond the bonded die structure 160 to the support structure 157.

In fabricating a bonded die structure 160 such as shown in FIG. 7, accurate alignment and positioning of the first die 110, and second die 210 remains a difficult challenge. This may be due, at least in part, to inaccuracies in the overlap measurement between the position of the first die 110, and second die 210 and the position of the first alignment marks 105, and second alignment marks 205. Referring again to FIG. 2, current systems used for obtaining overlap measurements, such as an above-described OM system 106 and/or an above-described IR inspection system 108, frequently produce inaccurate overlap measurement values. This may be due, at least in part, to the so-called “black edge” effect. There are two primary causes of the black edge effect. First, the peripheral edges 115, 215 of the first die 110 and second die 210 may not be perfectly vertical but may instead have a tilted, beveled or curved profile. This is illustrated in FIG. 2, which shows the edges 115 of the first die 110 having an outwardly tilted profile between the back (i.e., top) side 114 and the front (i.e., bottom) side 112 of the first die 110. Because the OM system 106 typically measures the distance between the alignment mark 105 and the peripheral edge 115 of the die 110, a tilted profile as shown in FIG. 2 can create ambiguity as to the precise location of the edge 115 and thus result in inaccuracies in the overlap measurement values. As illustrated in FIG. 2, there is an offset between the horizontal position of the peripheral edge 115 of the die 110 at the top of the die 110 (indicated by dashed line 301) and the position of the edge 115 at the bottom of the die 110 (indicated by dashed line 303). Thus, the position of the die's edge 115 as measured by the OM system 106 may have a zone of uncertainty as indicated by the offset distance, d_{off}, between lines 301 and 303 in FIG. 2. This can result in inaccurate and/or inconsistent overlap measurement values, which can lead to excessive overlay shift in the placement of dies 110 on the underlying structure(s).

Another cause of black edge effect is optical defocus aberrations in the OM equipment, which can result in a range of error in the measured position of the edge 115 of the die 110. Optical defocus issues can result in inaccurate overlap measurement values for dies 110 having non-vertical edges 115 such as shown in FIG. 2 as well as in dies 110 having vertical edges 115. Optical defocus issues can also result in significant measurement errors and high inconsistency using IR inspection systems 108.

Inaccurate overlap measurement values can result in excessive “overlay shift” in the placement of first die 110, second die 210 on the underlying structure(s). As discussed above, this can result in high electrical resistance across the bonding interface(s) between first die 110, second die 210 in a bonded die structure 160, which can lead to poor device performance and reduced yields. In addition, errors in die placement can also result in errors in the above-described dicing process, such as causing the dicing to be erroneously performed through portions of the first die 110 and second die 210 rather than through the gap fill dielectric material 130, which can damage the first die 110, second die 210 and render them non-functional.

Various embodiments include bonded die structures 160 and methods of fabricating bonded die structures 160 that include improved positioning of the first die 110 and second die 210 that form the bonded die structures 160. The improved positioning may be achieved by providing one or more non-linear alignment features around the periphery of the first die 110 and second die 210 that may facilitate more precise positioning of the first die 110 and second die 210 with respect to alignment marks, such as the above-described first alignment marks 105 and second alignment marks 205, disposed on the target structures on which the first die 110, second die 210 are placed. In some embodiments, the non-linear alignment features may include indent portions and/or outward bulge portions, in the peripheral edges 115 of the first die 110, and peripheral edges 115 of the second die 210 that may correspond to the locations of the first alignment marks 105 and second alignment marks 205 in the target structures. Alternatively, or in addition, the non-linear alignment features may include indent portions and/or outward bulge portions in a seal ring structure of the first die 110, second die 210. The non-linear alignment features may improve the accuracy of the optical detection of the position of the first die 110, second die 210 relative to the respective first alignment mark(s) 105, and second alignment marks 205.

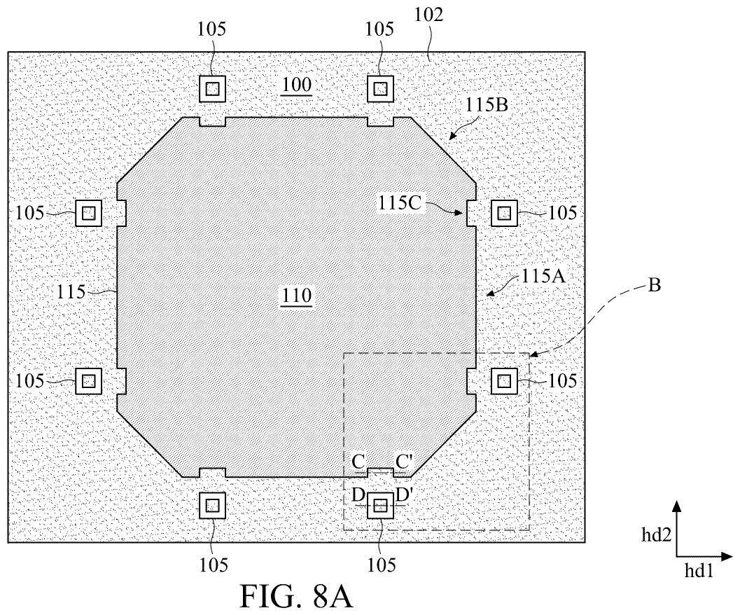

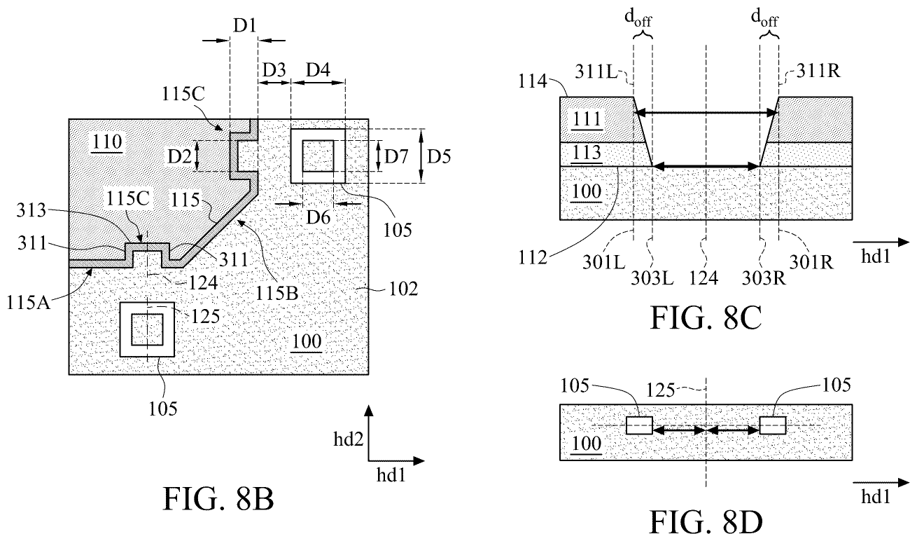

FIG. 8A is a top view of a first die 110 disposed on a first carrier structure 100 according to various embodiments of the present disclosure. The first die 110 and the carrier structure 100 shown in FIG. 8A may be equivalent to the first die 110 and the carrier structure 100 described above with reference to FIG. 2. Thus, repeated discussion of like features is omitted for brevity. FIG. 8A illustrates the shape of the peripheral edge 115 of the first die 110 according to various embodiments of the present disclosure. In the embodiment of FIG. 8A, the peripheral edge 115 of the first die 110 has a truncated quadrilateral shape including four side portions 115A and corner portions 115B extending between each adjacent pair of side portions 115A. Two of the side portions 115A extend parallel to one another along a first horizontal direction hd1 and two of the side portions 115A extend parallel to one another along a second horizontal direction hd2 that is perpendicular to the first horizontal direction hd1. Each of the corner portions 115B extends in a diagonal direction between adjacent pairs of side portions 115A. Although FIG. 8A illustrates the first die 110 having a peripheral shape in the form of a truncated quadrilateral, it will be understood that the first die 110 may have other shapes, such as other polygonal shapes (e.g., a quadrilateral shape, a triangle shape, etc.), a circular shape, an irregular shape, and so forth.

Referring again to FIG. 8A, in various embodiments the peripheral edge 115 of the first die 110 may further include a plurality of non-linear alignment features that may be in locations corresponding to the locations of respective alignment marks 105 of the first carrier structure 100. In the embodiment of FIG. 8A, the non-linear alignment features include indent portions 115C that extend inwardly from the respective side portions 115A of the peripheral edge 115 of the first die 110.

FIG. 8B is an enlarged view of region “B” of FIG. 8A. As shown in FIG. 8B, the indent portions 115C of the edge 115 of the first die 110 may include a rectangular shape when viewed in horizontal cross-section. That is, each of the indent portions 115C may include a pair of segments 311 extending inwardly from the side portion 115A in a direction perpendicular to the direction of the side portion 115A and a connecting segment 313 extending between the pair of segments 311 along a direction that is parallel to the direction of the side portion 115A. The shape of the indent portions 115C may be symmetric about a center line 124 that is perpendicular to the direction of the side portion 115A.

In various embodiments, a depth D1 of the indent portions 115C from the side portions 115A (i.e., a length of the segments 311) may be at least about 0.1 μm, such as between about 0.1 μm and about 5 μm, including between about 1 μm and about 3 μm (e.g., ˜2 μm). A width dimension D2 of the indent portions 115C (i.e., the length of the connecting segment 313) may be at least about 0.1 μm, such as between about 1 μm and about 60 μm, including between about 5 μm and about 40 μm (e.g., ˜30 μm). In some embodiments, the depth D1 of the indent portion 115C may be less than the width D2 of the indent portion 115C to minimize the possibility of crack formation in the first die 110.

In various embodiments, the shape of the peripheral edge 115 of the first die 110 may be formed during a dicing process used to separate the first die 110 from a larger support structure, such as a semiconductor wafer. As discussed above, semiconductor integrated circuits are typically fabricated by sequentially depositing insulating or dielectric layers, conductive layers, and/or semiconductive layers of material over a semiconductor substrate (e.g., a wafer), and patterning the various material layers using lithography to form integrated circuits. Portions of the semiconductor substrate containing separate integrated circuits thereon may then be separated (i.e., singulated) from the remainder of the semiconductor substrate via a dicing process to provide individual dies. The shape of the resultant dies may be determined based on the particular dicing process(es) that are used.

In some embodiments, the dicing process used to form the shape of the peripheral edge 115 of the first die may include a plasma etching process through a lithographically patterned mask. The mask may be patterned to include openings that may define the size, shape and locations of the indent portions 115C to be subsequently formed. In one non-limiting embodiment, the plasma etching process may include a pulsed or time-multiplexed process that alternates between an isotropic etching process (e.g., using a sulfur hexafluoride (SF₆) plasma) and the deposition of a thin passivation layer (e.g., using an octafluorocyclobutane (C₄F₈)) plasma) over the etched surfaces. During the subsequent etching process, directional ions attack and remove the passivation layer and the underlying material from surfaces perpendicular to the incident ions while the passivation layer protects sidewall surfaces from being etched. Repeating these etching and deposition steps over a number of iterations may provide a highly-directional etch that may produce relatively steep sidewalls. Following the plasma etching process, the mask may be removed using a suitable process, such as by ashing or dissolution using a solvent.

Referring again to FIGS. 8A and 8B, a plurality of first alignment marks 105 are shown on the front side 102 of the first carrier structure 100. In this embodiment, each of the first alignment marks 105 includes a square shape, although other shapes and designs for the first alignment marks 105 are within the contemplated scope of disclosure. In various embodiments, each of the first alignment marks 105 may be symmetric about a center line 124 that extends towards the target location for placement of the first die 110.

In various embodiments, the first alignment marks 105 may be distributed around the outer periphery of the target location for placement of the first die 110. The arrangement of the first alignment marks 105 may roughly correspond to the shape of the outer periphery of the first die 110, such that line segments connecting each of the adjacent first alignment marks 105 form a truncated quadrilateral shape that is similar to the shape of the first die 110. The locations of each first alignment mark 105 may correspond to the locations of a corresponding indent portion 115C of the first die 110. A target offset distance D3 between each of the first alignment marks 105 and the adjacent side portion 115A of the first die 110 may be at least about 0.1 μm, such as between about 0.1 μm and about 30 μm, including between about 5 μm and about 25 μm (e.g., ˜15 μm). In some embodiments, the target offset distance D3 may be about 0.5 times the width dimension D2 of the indent portions 115C of the first die 110.

Each first alignment mark 105 may have a first outer width dimension D4 along a first horizontal direction hd1 and a second outer width dimension D5 along a second horizontal direction hd2. In some embodiments, D4 may be equal to D5. In some embodiments, D4 and D5 may each be at least about 0.1 μm, such as between about 1 μm and about 60 μm, including between about 5 μm and about 40 μm (e.g., ˜30 μm). In some embodiments, D4 and D5 may be approximately equal to the width dimension D2 of the indent portions 115C of the first die 110. In some embodiments, 0.5*D4≤D3≤5*D4 and/or 0.5*D5≤D3≤5*D5.

Each first alignment mark 105 may also have a first inner width dimension D6 along the first horizontal direction hd1 and a second inner width dimension D7 along the second horizontal direction hd2. In some embodiments, D6 may be equal to D7. In some embodiments, D6 and D7 may each be at least about 0.1 μm, such as between about 1 μm and about 50 μm, including between about 3 μm and about 30 μm (e.g., ˜20 μm).

FIG. 8C is a vertical cross-sectional view of a portion of the first carrier structure 100 and the first die 110 taken along line C-C′ in FIG. 8A. FIG. 8D is a vertical cross-sectional view of a portion of the first carrier structure 100 and a first alignment mark 105 taken along line D-D′ in FIG. 8A. Referring to FIGS. 8C and 8D, to place the first die 110 on the first carrier structure 100, an above-described pick-and-place tool 107 may position the first die 110 over the target area of the first carrier structure 100 such that each indent portion 115C of the first die 110 is located adjacent to a corresponding alignment mark 105 of the first carrier structure 100. In some embodiments, the first die 110 may be placed down onto the front side 102 of the first carrier structure 100. Alternatively, the first die 110 may be held slightly above the front side 102 of the first carrier structure 100. An optical detection system, such as an above-described OM system 106, may be utilized to measure the positions of the indent portions 115C viz-a-viz the corresponding alignment mark 105 of the first carrier structure 100. Referring to FIG. 8C, in some embodiments, measuring the positions of the indent portions 115C may include measuring the position of the die edge 115 on each of the segments 311L, 311R of the indent portion 115C located on opposite (i.e., left and right) sides of the indent portion 115C. Because both segments 311L and 311R of the indent portions 115C are formed at the same time under the same process conditions, the tilt profiles along each segment 311L and 311R (i.e., the difference in the respective positions of the segments 311L, 311R between the top and bottom of the die indicated by dashed lines 301L, 303L, 301R and 303R) should be approximately equal, resulting in substantially equal offset distances, d_{off}, as shown in FIG. 8C. Accordingly, measurement errors due to the tilt profile of the segments 311L and 311R should generally cancel each other out. A horizontal position of the indent portion 115C may be determined by calculating the position of the centerline 124 (i.e., the midpoint between the left-and right-hand segments 311L and 311R) of the indent portion 115C based on the detected positions of the segments 311L and 311R. This may be done for each of the indent portions 115C along the periphery of the first die 110.

The optical detection system may similarly measure the positions of each of the first alignment marks 105. For example, the optical detection system may measure the positions at two locations on opposite sides of the first alignment mark 105 and based on these measurements calculate the position of the centerline 125 of the first alignment mark 105, as shown in FIG. 8D. The lateral offset between the positions of the centerline 124 of each indent portion 115C and the centerline 125 of the corresponding first alignment mark 105 may define an offset measurement value for each set of indent portions 115C and the corresponding first alignment mark 105. In the event that one or more of the offset measurement values is greater than a pre-determined threshold value (e.g., 1 μm, 0.5 μm, 0.1 μm, etc.) the position of the first die 110 may be adjusted and the above-described measurement process may be repeated until all of the offset measurement values are at or below the threshold value, in which case the first die 110 may be considered to be properly located on the first carrier structure 100.

In some embodiments, determining the offset measurement values for two indent portions 115C located on different side portions 115A of the first die 110 that extend perpendicular to one another may be sufficient to fully determine whether or not the first die 110 is properly placed. This is because determining that an indent portion 115C is properly aligned with the corresponding first alignment mark 105 along a first horizontal direction (e.g., hd1) may indicate that the offset distance D3 along the second horizontal direction (e.g., hd2) is within the target range, while determining that another indent portion 115C is properly aligned with the corresponding first alignment mark 105 along the second horizontal direction (e.g., hd2) may indicate that the offset distance D3 along the first horizontal direction (e.g., hd1) is within the target range.

However, for improved accuracy, it may be beneficial to determine offset measurement values for more than two indent portions 115C, including for all of the indent portions 115C around the periphery of the first die 110.

The process described above with reference to FIGS. 8A-8D may be repeated when placing the second die 210 onto the planar surface 128 formed by the first dielectric material 130 and the first die 110 as described above with reference to FIG. 4. That is, the second die 210 may include one or more non-linear alignment features such as one or more indent portions 115C along the peripheral edge 215 of the second die 210. The second alignment marks 205 may be distributed around the outer periphery of the target location for placement of the second die 210, where locations of each second alignment mark 205 may correspond to the locations of a corresponding indent portion 115C of the second die 210. An optical detection system, such as an above-described OM system 106, may be utilized to measure the positions of the indent portions 115C viz-a-viz the corresponding second alignment marks 205 to determine the offset measurement values as described above and the position of the second die 210 may be adjusted as necessary until the offset measurement values are each within the threshold values indicating that the second die 210 is properly located.

The additional process steps described above with reference to FIGS. 4-7 may then be performed to provide an above-described bonded die structure 160. In various embodiments, the indent portions 115C of the first die 110 and/or the second die 210 may be filled by the first gap fill dielectric material 130, and second gap fill dielectric material 230. In some embodiments, the bonded die structure 160 may include one or more alignment mark structures 216 that may be embedded in the first gap fill dielectric material 130, and second gap fill dielectric material 230. The location of each alignment mark structure 216 may correspond to the location of a non-linear alignment feature (e.g., an indent portion 115C) along the adjacent side portion 115A of the peripheral edge 215 of the second die 210. The centerline 125 of the alignment mark structure 216 may intersect the non-linear alignment feature (e.g., indent portion 115C) along the adjacent side portion 115A of the peripheral edge 215 of the second die 210. The alignment mark structure(s) 216 may be separated from the adjacent side portion 115A of the peripheral edge 215 of the second die 210 by the offset distance D3.

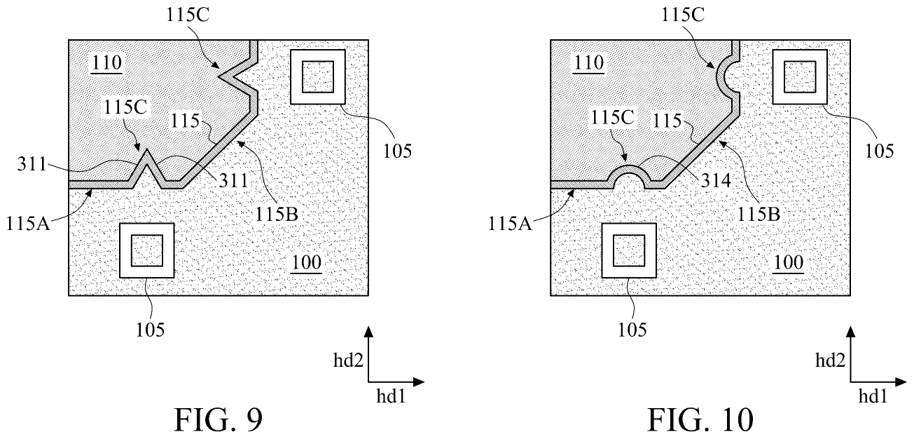

FIG. 9 is a top view of a portion of a first die 110 disposed on a first carrier structure 100 according to another embodiment of the present disclosure. Referring to FIG. 9, the first die 110 in this embodiment includes indent portions 115C having a triangular shape. The indent portions 115C may include a pair of segments 311 extending inwardly from the side portion 115A at an angle and meeting at a vertex. The indent portions 115C shown in FIG. 9 may be formed using the same method(s) as described above with reference to FIGS. 8A-8D. The dimensions of the indent portions 115C and the first alignment marks 105, including the depth D1 and width D2 of the indent portions 115C and the target offset distance D3 between the side portion 115A and the first alignment mark 105 may be equivalent to those described above with reference to FIG. 8B. The placement of the first die 110 and determination of the offset measurement values may be the same as described above with reference to FIGS. 8C and 8D. In particular, the optical detection system may measure the positions of the pair of segments 311 on opposite sides of the indent portion 115C to determine the position of the centerline 124 of the indent portion 115C and compare it to the position of the centerline 125 of the first alignment mark 105. The position of the first die 110 may be adjusted as necessary until the offset measurement value is below the predetermined threshold value. Although FIG. 9 illustrates a first die 110, it will be understood that a second die 210 as described above may also include triangular shaped indent portions 115C as shown in FIG. 9.

FIG. 10 is a top view of a portion of a first die 110 disposed on a first carrier structure 100 according to another embodiment of the present disclosure. Referring to FIG. 10, the first die 110 in this embodiment includes indent portions 115C having a semicircular shape. The indent portions 115C may include a single segment extending inwardly from the side portion 115A along an arc. The indent portions 115C shown in FIG. 10 may be formed using the same method(s) as described above with reference to FIGS. 8A-8D. The dimensions of the indent portions 115C and the first alignment marks 105, including the depth D1 and width D2 of the indent portions 115C and the target offset distance D3 between the side portion 115A and the first alignment mark 105 may be equivalent to those described above with reference to FIG. 8B. The placement of the first die 110 and determination of the offset measurement values may be the same as described above with reference to FIGS. 8C and 8D. In particular, the optical detection system may measure the positions of the curved segment 314 on opposite sides of the indent portion 115C to determine the position of the centerline 124 of the indent portion 115C and compare it to the position of the centerline 125 of the first alignment mark 105. The position of the first die 110 may be adjusted as necessary until the offset measurement value is below the predetermined threshold value. Although FIG. 10 illustrates a first die 110, it will be understood that a second die 210 as described above may also include semicircular shaped indent portions 115C as shown in FIG. 10.

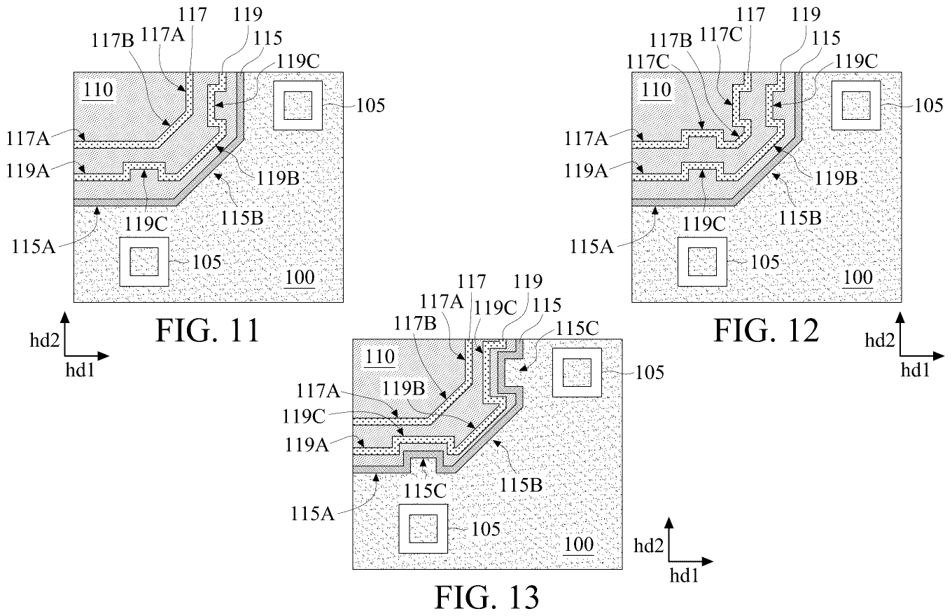

In further embodiments, the non-linear alignment features of the first die 110, second die 210 may include features of the seal ring(s). FIG. 11 is a top view of a portion of a first die 110 disposed on a first carrier structure 100 according to another embodiment of the present disclosure. The first die 110 in the embodiment of FIG. 11 differs from the embodiments shown in FIGS. 8A-10 in that the peripheral edge 115 of the first die 110 does not include indent portions 115C located in the side portions 115A of the first die 110. FIG. 11 also illustrates the location of the above-described seal ring 117 in the first die 110. As discussed above, the seal ring 117 extends around the first die 110 near the peripheral edge 115 of the die and may have a shape that corresponds to the shape of the first die 110. In the embodiment shown in FIG. 11, for example, the seal ring 117 may have a truncated quadrilateral shape including side portions 117A connected by corner portions 117B. The first die 110 shown in FIG. 11 additionally includes a second seal ring 119 that is located between the seal ring 117 and the peripheral edge 115 of the first die 110. In other embodiments, the seal ring 117 may be located between the second seal ring 119 and the peripheral edge 115 of the first die 110. The second seal ring 119 may have a similar shape as seal ring 117 and may include side portions 119A connected by corner portions 119B. The second seal ring 119 may differ from the seal ring 117 in that the second seal ring 119 may include indent portions 119C extending inwardly from the side portions 119A of the second seal ring 119. The locations of each indent portion 119C may correspond to the location of a first alignment mark 105 of the first carrier structure 100. The dimensions of the indent portions 119C of the second seal ring 119, including the depth and width of the indent portions 119C, may be equivalent to those of the indent portions 115C along the peripheral edge 115 of the first die 110 as described above with reference to FIGS. 8A-10. Further, although in the embodiment shown in FIG. 11, the indent portions 119C have a rectangular shape, it will be understood that the indent portions 119C may have other shapes, such as a triangular shape or a semicircular shape. In addition, although FIG. 11 illustrates an embodiment including multiple seal rings 117 and 119 where one of the seal rings includes indent portions 119C, it will be understood that in some embodiments, the first die 110 may include a single seal ring including indent portions.

The placement of the first die 110 and determination of the offset measurement values may be similar to as described above with reference to FIGS. 8C and 8D. In particular, an optical detection system, such as an above-described IR inspection system 108, may be used to measure the positions of the second seal ring 119 on opposite sides of the indent portion 119C to determine the position of the centerline of the indent portion 119C. By measuring the position of the second seal ring 119 in two locations on opposite sides of the indent portion 119C, measurement errors resulting from optical defocus issues in the IR inspection system 108 may be minimized. The position of the centerline of the indent portion 119C may be compared to the measured position of the centerline of the corresponding first alignment mark 105, as described above. The position of the first die 110 may be adjusted as necessary until the offset measurement value is below the predetermined threshold value. Although FIG. 11 illustrates a first die 110, it will be understood that a second die 210 as described above may also include a second seal ring 119 including indent portions 119C as shown in FIG. 11.

FIG. 12 is a top view of a portion of a first die 110 disposed on a first carrier structure 100 according to another embodiment of the present disclosure. The first die 110 shown in FIG. 12 is similar to the first die 110 of FIG. 11, except that the seal ring 117 in the embodiment of FIG. 12 additionally includes indent portions 117C extending inwardly from the side portions 117A of the second seal ring 117. The locations of the indent portions 117C the seal ring 117 may correspond to the locations of the indent portions 119C of the second seal ring 119 and to a corresponding first alignment mark 105 of the first carrier structure 100. The size and/or shape of the indent portions 117C of the seal ring 117 may be the same as or may be different than the size and/or shape of the indent portions 119C of the second seal ring 119. In some embodiments, the centerlines of the indent portions 117C of the seal ring 117 may be the same as the centerlines of the corresponding indent portions 119C of the second seal rings 119.

The placement of the first die 110 and determination of the offset measurement values may be similar to as described above with reference to FIG. 11. In some embodiments, by measuring the positions of multiple indent portions 117C and 119C, measurement errors resulting from optical defocus issues in the IR inspection system 108 may be further minimized. In some embodiments, where there the centerline positions of the indent portions 117C and 119C differ, an average centerline position may be determined and compared to the measured position of the centerline of the corresponding first alignment mark 105, as described above. The position of the first die 110 may be adjusted as necessary until the offset measurement value is below the predetermined threshold value. Although FIG. 12 illustrates a first die 110, it will be understood that a second die 210 as described above may also include multiple seal rings 117 and 119 including indent portions 117C and 119C as shown in FIG. 12.

FIG. 13 is a top view of a portion of a first die 110 disposed on a first carrier structure 100 according to another embodiment of the present disclosure. In the embodiment of FIG. 13, the first die 110 may include multiple non-linear alignment features as described above, including indent portions 115C along the peripheral edge 115 of the first die 110 as well as indent portions 119C in the second seal ring 119. One or both of the indent portions 115C and 119C may be utilized for positioning of the first die 110 on the first carrier structure 100 as described above. A configuration as shown in FIG. 13 may also be utilized for an above-described second die 210.

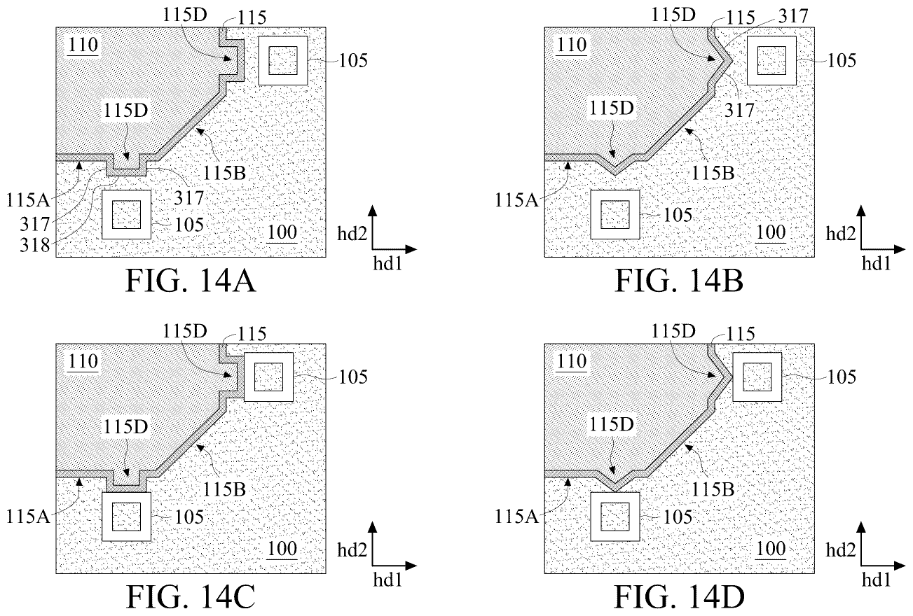

In further embodiments, the non-linear alignment features of the first die 110, second die 210 may include an outward bulge portion of the first peripheral edge of the first die 110, and second peripheral edge 215 of second die 210. FIG. 14A is a top view of a portion of a first die 110 disposed on a first carrier structure 100 including outward bulge portions 115D that extend outwardly from the respective side portions 115A of the peripheral edge 115 of the first die 110 according to another embodiment of the present disclosure. The outward bulge portions 115D in this embodiment include a rectangular shape including a pair of segments 317 extending outwardly from the side portion 115A in a direction perpendicular to the direction of the side portion 115A and a connecting segment 318 extending between the pair of segments 317 along a direction that is parallel to the direction of the side portion 115A. The outward bulge portions 115D shown in FIG. 14A may be formed using the same method(s) as described above with reference to FIGS. 8A-8D. The dimensions of the outward bulge portions 115D, including the depth (i.e., outward distance from the side portion 115A) and width of the outward bulge portions 115D and the target offset distance between the side portion 115A and the first alignment mark 105 may be consistent to those described above with reference to FIG. 8B. The locations of the outward bulge portions 115D may correspond to the locations of the first alignment marks 105 on the first carrier structure 100.

The placement of the first die 110 and determination of the offset measurement values may be the same as described above with reference to FIGS. 8C and 8D. In particular, the optical detection system may measure the positions of the pair of segments 317 on opposite sides of the outward bulge portion 115D to determine the position of the centerline of the outward bulge portion 115D and compare it to the position of the centerline of the first alignment mark 105. The position of the first die 110 may be adjusted as necessary until the offset measurement value is below the predetermined threshold value. Although FIG. 14A illustrates a first die 110, it will be understood that a second die 210 as described above may also include outward bulge portions 115D as shown in FIG. 14B.

FIG. 14B is a top view of a portion of a first die 110 disposed on a first carrier structure 100 according to another embodiment of the present disclosure. Referring to FIG. 14B, the first die 110 in this embodiment includes outward bulge portions 115D having a triangular shape. The outward bulge portions 115D may include a pair of segments 317 extending outwardly from the side portion 115A at an angle and meeting at a vertex. The dimensions of the outward bulge portions 115D and the first alignment marks 105, including the depth and width of the outward bulge portion 115D and the target offset distance D3 between the side portion 115A and the first alignment mark 105 may be equivalent to those described above with reference to FIG. 8B.

The placement of the first die 110 and determination of the offset measurement values may be the same as described above with reference to FIGS. 8C and 8D. In particular, the optical detection system may measure the positions of the pair of segments 317 on opposite sides of the outward bulge portion 115D to determine the position of the centerline of the outward bulge portion 115D and compare it to the position of the centerline of the first alignment mark 105. The position of the first die 110 may be adjusted as necessary until the offset measurement value is below the predetermined threshold value. Although FIG. 14B illustrates a first die 110, it will be understood that a second die 210 as described above may also include triangular shaped outward bulge portions 115D as shown in FIG. 14B. It will be understood that other shapes for the outward bulge portion 115D, such as a semicircular shape, may also be utilized.

In some embodiments, the depth of the outward bulge portion 115B from the side portion 115A of the first die 110 may be greater than the offset distance D3 between the first alignment mark 105 and the side portion 115A of the first die 110. In such cases, the outward bulge portion 115B may at least partially overlap with the first alignment mark 105. FIG. 14C is a top view of a portion of a first die 110 disposed on a first carrier structure 100 including outward bulge portions 115D that partially overlap the corresponding first alignment marks 105 according to an embodiment of the present disclosure. The outward bulge portions 115D in FIG. 14C have a rectangular shape as described above with reference to FIG. 14A. The placement of the first die 110 and determination of the offset measurement values may be the same as described above with reference to FIG. 14A. FIG. 14D is a top view of a portion of a first die 110 disposed on a first carrier structure 100 including outward bulge portions 115D having triangular shapes that partially overlap the corresponding first alignment marks 105 according to another embodiment of the present disclosure.

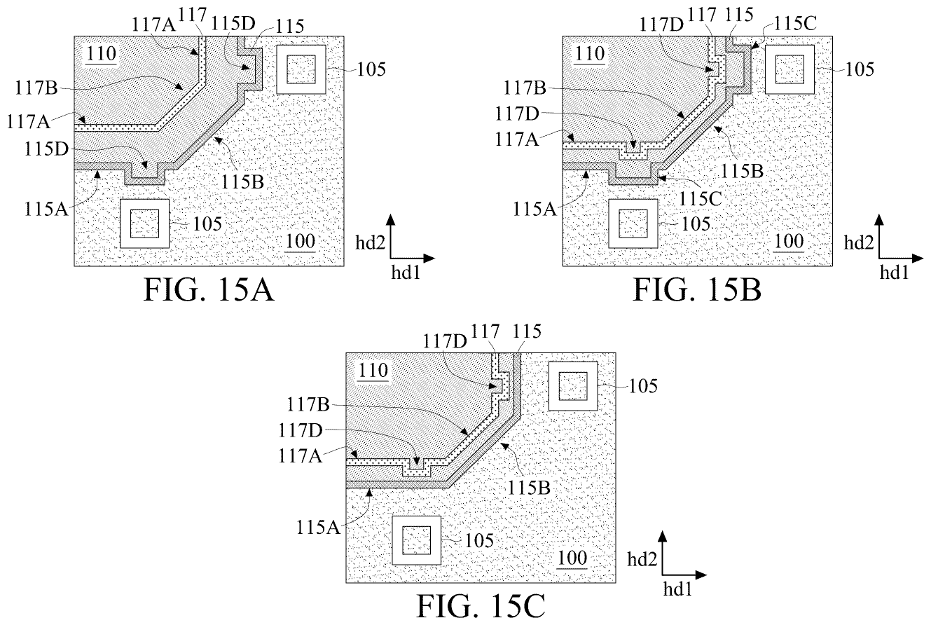

FIGS. 15A-15C are top views of a portion of a first die 110 disposed on a first carrier structure 100 in accordance with various additional embodiments of the present disclosure. The embodiment of FIG. 15A is similar to the embodiment of FIG. 14A including outward bulge portions 115D of the peripheral edge 115 of the first die 110 as described above and also illustrates the location of a seal ring 117 around the periphery of the first die 110. In this embodiment, the seal ring 117 includes side portions 117A connected by corner portions 117B, but the seal ring 117 does not include non-linear alignment features. FIG. 15B illustrates an embodiment in which both the peripheral edge 115 of the first die 110 and the seal ring 117 include non-linear alignment features 115D and 117D. The peripheral edge 115 of the first die 110 includes outward bulge portions 115D corresponding to the locations of the first alignment marks 105 as described above. The seal ring 117 additionally includes outward bulge portions 117D corresponding to the locations of the first alignment marks 105. One or both of the outward bulge portions 115D and 117D may be utilized for positioning of the first die 110 on the first carrier structure 100 as described above. FIG. 15C illustrates an embodiment in which the seal ring 117 includes an outward bulge portion 117D and the peripheral edge 115 of the first die 110 does not include non-linear alignment features. A configuration as shown in any of FIGS. 15A-15C may also be utilized for an above-described second die 210.

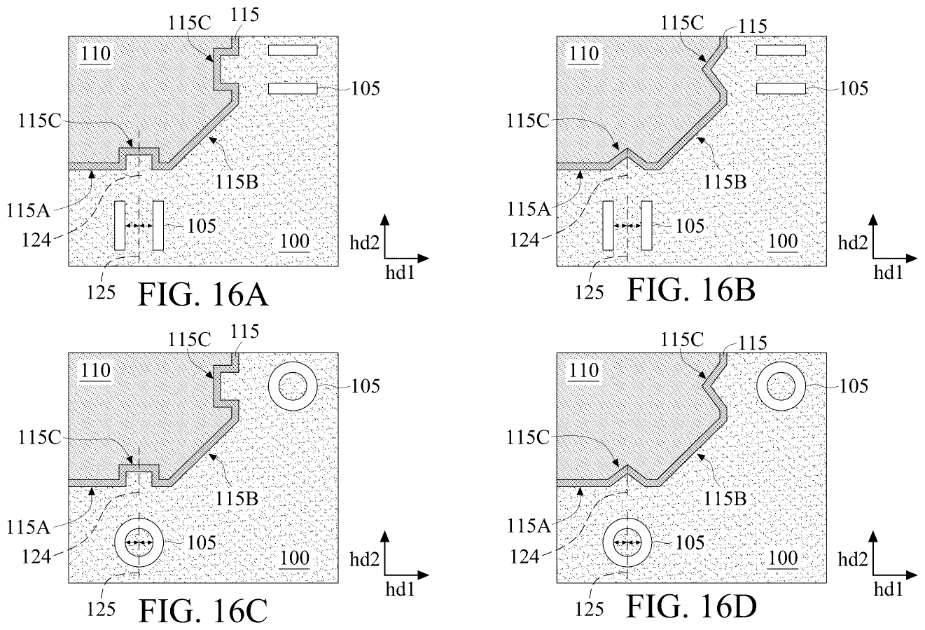

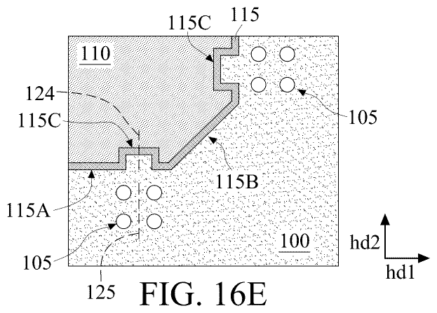

FIGS. 16A-16E are top views of a portion of a first die 110 disposed on a first carrier structure 100 illustrating various configurations of non-linear alignment features in the peripheral edge 115 of the first die 110 and first alignment marks 105 in accordance with various embodiments of the present disclosure. FIG. 16A illustrates the first die 110 having rectangular shaped indent portions 115C as described above.

The first alignment marks 105 in this embodiment include two lines extending parallel to one another and perpendicular to the adjacent side portion 115A of the edge 115 of the first die 110. The embodiment of FIG. 16B similarly illustrates first alignment marks 105 including two parallel lines where the peripheral edge 115 of the first die 110 in this embodiment includes triangular shaped indent portions 115C.

FIG. 16C illustrates the first die 110 having rectangular shaped indent portions 115C as described above. The first alignment marks 105 in this embodiment include a circular shape. In the embodiment of FIG. 16D, the first die 110 includes triangular shaped indent portions 115C and the first alignment marks 105 include a circular shape. In the embodiment of FIG. 16E, the first die 110 includes rectangular shaped indent portions 115C and the first alignment marks 105 include four dots corresponding to the vertices of a square. In each of the embodiments shown in FIGS. 16A-16E, both the non-linear alignment features (i.e., indent portions 115C) of the first die 110 and the first alignment marks 105 are symmetric about respective centerlines 124 and 125. The first die 110 may be positioned on the first carrier structure 100 by aligning the centerlines 124 of the non-linear alignment features with the centerlines 125 of the corresponding first alignment marks 105. The dimensions of the non-linear alignment features 115C and of the first alignment marks 105 may be equivalent to those described above with reference to FIG. 8B in each of the embodiments shown in FIGS. 16A-16E. A configuration as shown in any of FIGS. 16A-16E may also be utilized for an above-described second die 210 and/or second alignment mark 205.

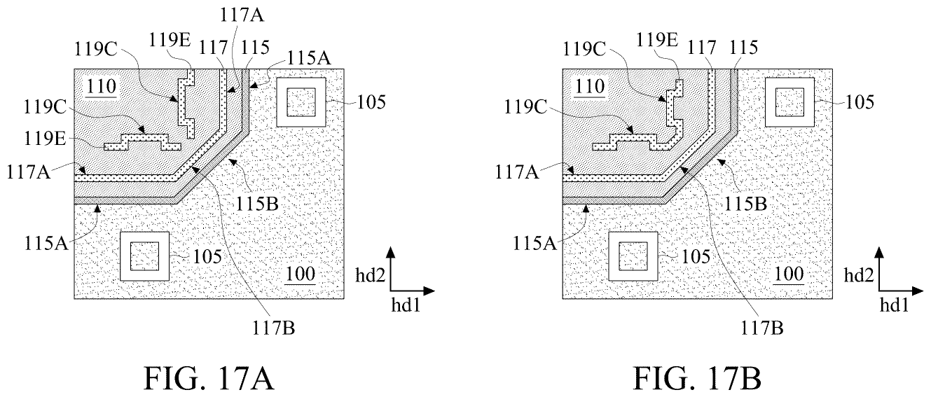

FIGS. 17A and 17B are top views of a portion of a first die 110 disposed on a first carrier structure 100 illustrating discontinuous second seal ring segments 119E having non-linear alignment features 119C in accordance with various embodiments of the present disclosure. Referring to FIG. 17A, the first die 110 includes a peripheral edge 115 and a first seal ring 117 that do not include non-linear alignment features. The first die 110 additionally includes a plurality of discontinuous second seal ring segments 119E, where each discontinuous second seal ring segment 119E includes a non-linear alignment feature. The discontinuous second seal ring segments 119E may be discontinuous in that they do not extend around the entire periphery of the first die 110. In the embodiment shown in FIG. 17A, the non-linear alignment features include indent portions 119C as described above with reference to FIGS. 11-13. FIG. 17A illustrates the seal ring 117 located between the peripheral edge 115 of the first die 110 and the discontinuous seal ring segments 119E, although it will be understood that the discontinuous seal ring segments 119E may be located between the peripheral edge 115 of the first die 115 and the seal ring 117. In other embodiments, the discontinuous seal ring segments 119E may include outward bulge portion 115D as described above with reference to FIGS. 15B and 15C. The indent portions 119C and/or outward bulge portions 117D may have any suitable shape, such as a rectangular shape as shown in FIG. 17A, a triangular shape, a semicircular shape, etc.

Although FIG. 17A illustrates each of the discontinuous seal ring segments 119E including a single non-linear alignment feature, in other embodiments, the first die 110 may include at least one discontinuous seal ring segment 119E including multiple non-linear alignment features. FIG. 17B illustrates an alternative embodiment in which a discontinuous seal ring segment 119E includes two non-linear alignment features (i.e., indent portions 119C) each corresponding to the location of a different alignment mark 105 of the first carrier structure 100. The discontinuous seal ring segment 119E in this embodiment is located near a corner portion 115B of the first die 110. A configuration as shown in any of FIGS. 16A and 17B may also be utilized for an above-described second die 210 in various embodiments.

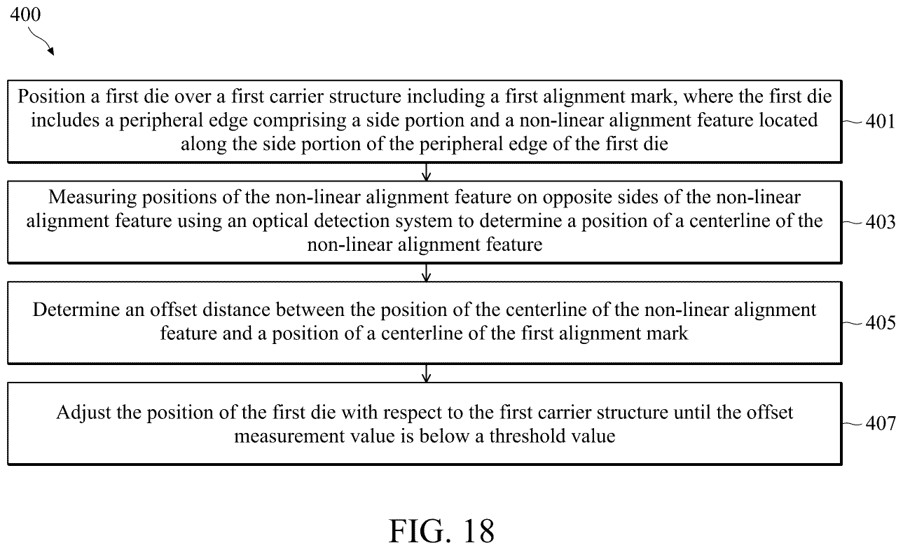

FIG. 18 is a flowchart illustrating a method 400 of fabricating a bonded die structure 160 according to various embodiments of the present disclosure. Referring to FIGS. 2 and 8A-18, in step 401 of method 400, a first die 110 may be positioned over a first carrier structure 100 including a first alignment mark 105, where the first die 110 includes a peripheral edge 115 including a side portion 115A and a non-linear alignment feature 115C, 115D, 117C, 117D, 118C located along the side portion 115A of the peripheral edge 115 of the first die 110. Referring to FIGS. 2 and 8A-18, in step 403 of method 400, positions of the non-linear alignment feature 115C, 115D, 117C, 117D, 118C may be measured on opposite sides of the non-linear alignment feature 115C, 115D, 117C, 117D, 118C using an optical detection system 106, 108 to determine a position of a centerline 124 of the non-linear alignment feature 115C, 115D, 117C, 117D, 118C. Referring to FIGS. 2 and 8A-18, in step 405 of method 400, an offset distance between a position of the centerline 124 of the non-linear alignment feature 115C, 115D, 117C, 117D, 118C and a position of a centerline 125 of the first alignment mark 105 may be determined. Referring to FIGS. 2 and 8A-18, in step 407 of method 400, the position of the first die 110 with respect first carrier structure 100 may be adjusted until the offset distance is below a threshold value.

Referring to all drawings and according to various embodiments of the present disclosure, a bonded die structure 160 includes a first die 110 having a peripheral edge 115 including a side portion 115A and a non-linear alignment feature 115C, 115D, 117C, 117D, 118C located along the side portion 115A of the peripheral edge 115 of the first die 110, and a second die 210 bonded to the first die 110.

In one embodiment, the peripheral edge 115 of the first die 110 includes a first side portion 115A extending along a first direction hd1 and a second side portion 115A extending along a second direction hd2 that is perpendicular to the first direction hd1, where a first non-linear alignment feature 115C, 115D, 117C, 117D, 118C is located along the first side portion 115A and a second non-linear alignment feature 115C, 115D, 117C, 117D, 118C is located along the second side portion 115A.

In another embodiment, the peripheral edge 115 of the first die 110 includes a truncated quadrilateral shape comprising four side portions 115A and corner portions 115B extending between adjacent side portions 115A, where at least two non-linear alignment features 115C, 115D, 117C, 117D, 118C are located along each of the side portions.

In another embodiment, the non-linear alignment feature includes an indent portion 115C extending inwards from the side portion 115A of the peripheral edge 115 of the first die 115. In another embodiment, a width D2 of the indent portion 115A along a direction parallel to the side portion 115A of the peripheral edge 115 of the first die 110 is greater than a depth D1 of the indent portion 115A along a direction perpendicular to the side portion 115A of the peripheral edge 115 of the first die 110. In another embodiment, the indent portion 115A has a rectangular, triangular or semicircular shape in horizontal cross-sectional. In another embodiment, the non-linear alignment feature includes an outward bulge portion 115D extending outwards from the side portion 115A of the peripheral edge 115 of the first die 110. In another embodiment, the outward bulge portion 115D has a rectangular, triangular or semicircular shape in horizontal cross-sectional. In another embodiment, the non-linear alignment feature includes an indent portion 117C, 119C of a seal ring structure 117, 119, 119E of the first die 110. In another embodiment, the non-linear alignment feature includes an outward bulge portion 117D of a seal ring structure 117, 119, 119E of the first die 110. In another embodiment, the peripheral edge 115 of the first die 110 has a non-vertical profile. In another embodiment, the bonded die structure 160 further includes a carrier structure 200, the second die 210 located between the carrier structure 200 and the first die 110, and a gap fill dielectric material 130, 230 laterally surrounding the first die 110 and the second die 210. In another embodiment, the second die 210 includes a peripheral edge 215 including at least one side portion 115A and a non-linear alignment feature 115C, 115D, 117C, 117D, 118C located along the at least one side portion 115A of the peripheral edge 215 of the second die 210.

Another embodiment is drawn to a bonded device structure 160 including a first die 110, a second die 210 including a peripheral edge 215 including a side portion 215 and a non-linear alignment feature 115C, 115D, 117C, 117D, 118C located along the side portion 115A of the peripheral edge 215 of the second die 210, and a gap fill dielectric material 130, 230 laterally surrounding the peripheral edge 215 of the second die 210.

In one embodiment, the bonded device structure 160 further includes an alignment mark structure 216 formed within the gap fill dielectric material 130, 230, where a centerline of the alignment mark structure 216 intersects the non-linear alignment feature 115C, 115D, 117C, 117D, 118C located along the side portion 115A of the peripheral edge 215 of the second die 210. In another embodiment, the non-linear alignment feature includes an outward bulge portion 115D extending outwards from the side portion 115A of the peripheral edge 215 of the second die 210, and the outward bulge portion 115D at least partially overlaps the alignment mark structure 216.

Another embodiment is drawn to a method of fabricating a bonded die structure 160 that includes positioning a first die 110 over a first carrier structure 100 including a first alignment mark 105, where the first die 110 includes a peripheral edge 115 having a side portion 115A and a first non-linear alignment feature 115C, 115D, 117C, 117D, 118C located along the side portion 115A of the peripheral edge 115 of the first die 110, measuring positions of the first non-linear alignment feature 115C, 115D, 117C, 117D, 118C on opposite sides of the first non-linear alignment feature 115C, 115D, 117C, 117D, 118C using an optical detection system 106, 108 to determine a position of a centerline 124 of the first non-linear alignment feature 115C, 115D, 117C, 117D, 118C, determining an offset distance between the centerline 124 of the first non-linear alignment feature 115C, 115D, 117C, 117D, 118C and a centerline 125 of the first alignment mark 105, and adjusting the position of the first die 110 with respect to the first carrier structure 100 until the offset distance is below a threshold value.

In one embodiment, the method further includes forming a first dielectric material layer 130 over the first carrier structure 100 and laterally surrounding the first die 110 disposed on the first carrier structure 100, forming a second alignment mark 205, positioning a second die 210 over the first die 110, the second die 210 including a peripheral edge 215 including a side portion 115A and a second non-linear alignment feature 115C, 115D, 117C, 117D, 118C located along the side portion 115A of the peripheral edge 215 of the second die 210, measuring positions of the second non-linear alignment feature 115C, 115D, 117C, 117D, 118C on opposite sides of the second non-linear alignment feature 115C, 115D, 117C, 117D, 118C using an optical detection system 106. 108 to determine a position of a centerline 124 of the second non-linear alignment feature 115C, 115D, 117C, 117D, 118C, determining an offset distance between the centerline 124 of the second non-linear alignment feature 115C, 115D, 117C, 117D, 118C and a centerline 125 of the second alignment mark 205, and adjusting the position of the second die with respect to the first die until the offset distance is below a threshold value. In another embodiment, the method further includes bonding the second die 210 to the first die 110, forming a second dielectric material layer 230 over the first dielectric material layer 130 and laterally surrounding the second die 210, transferring the first die 110, the first dielectric material layer 130, the second die 210, and the second dielectric layer 230 from the first carrier structure 100 to a second carrier structure 200 such that the second die 210 is located between the first die 110 and the second carrier structure 200, and performing a dicing process through the first dielectric material layer 130, the second dielectric layer 230 and the second carrier structure 200 to form the bonded device structure 160. In another embodiment, the second die 210 is bonded to the first die 110 using a dielectric-to-dielectric (D-D) and metal-to-metal (M-M) direct bonding technique.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A bonded die structure, comprising:
a first die comprising a peripheral edge comprising a side portion and a non-linear alignment feature located along the side portion of the peripheral edge of the first die; and
a second die bonded to the first die.

2. The bonded die structure of claim 1, wherein the peripheral edge of the first die comprises a first side portion extending along a first direction and a second side portion extending along a second direction that is perpendicular to the first direction, wherein a first non-linear alignment feature is located along the first side portion and a second non-linear alignment feature is located along the second side portion.

3. The bonded die structure of claim 1, wherein the peripheral edge of the first die comprises a truncated quadrilateral shape comprising four side portions and corner portions extending between adjacent side portions, wherein at least two non-linear alignment features are located along each of the side portions.

4. The bonded die structure of claim 1, wherein the non-linear alignment feature comprises an indent portion extending inwards from the side portion of the peripheral edge of the first die.

5. The bonded die structure of claim 4, wherein a width of the indent portion along a direction parallel to the side portion of the peripheral edge of the first die is greater than a depth of the indent portion along a direction perpendicular to the side portion of the peripheral edge of the first die.

6. The bonded die structure of claim 4, wherein the indent portion has a rectangular, triangular or semicircular shape in horizontal cross-sectional.

7. The bonded die structure of claim 1, wherein the non-linear alignment feature comprises an outward bulge portion extending outwards from the side portion of the peripheral edge of the first die.

8. The bonded die structure of claim 7 wherein the outward bulge portion has a rectangular, triangular or semicircular shape in horizontal cross-sectional.

9. The bonded die structure of claim 1, wherein the non-linear alignment feature comprises an indent portion of a seal ring structure of the first die.

10. The bonded die structure of claim 1, wherein the non-linear alignment feature comprises an outward bulge portion of a seal ring structure of the first die.

11. The bonded die structure of claim 1, wherein the peripheral edge of the first die has a non-vertical profile.

12. The bonded die structure of claim 1, further comprising:
a carrier structure, the second die located between the carrier structure and the first die; and
a gap fill dielectric material laterally surrounding the first die and the second die.

13. The bonded die structure of claim 1, wherein the second die comprises a peripheral edge comprising at least one side portion and a non-linear alignment feature located along the at least one side portion of the peripheral edge of the second die.

14. A bonded die structure, comprising:
a first die;
a second die comprising a peripheral edge comprising a side portion and a non-linear alignment feature located along the side portion of the peripheral edge of the second die; and
a gap fill dielectric material laterally surrounding the peripheral edge of the second die.

15. The bonded die structure of claim 14, further comprising:
an alignment mark structure formed within the gap fill dielectric material, wherein a centerline of the alignment mark structure intersects the non-linear alignment feature located along the side portion of the peripheral edge of the second die.

16. The bonded die structure of claim 15, wherein the non-linear alignment feature comprises an outward bulge portion extending outwards from the side portion of the peripheral edge of the second die, and the outward bulge portion at least partially overlaps the alignment mark structure.

17. A method of fabricating a bonded die structure, comprising:
positioning a first die over a first carrier structure comprising a first alignment mark, wherein the first die comprises a peripheral edge comprising a side portion and a first non-linear alignment feature located along the side portion of the peripheral edge of the first die;
measuring positions of the first non-linear alignment feature on opposite sides of the first non-linear alignment feature using an optical detection system to determine a position of a centerline of the first non-linear alignment feature;
determining an offset distance between the centerline of the first non-linear alignment feature and a centerline of the first alignment mark; and
adjusting the position of the first die with respect to the first carrier structure until the offset distance is below a threshold value.

18. The method of claim 17, further comprising:
forming a first dielectric material layer over the first carrier structure and laterally surrounding the first die disposed on the first carrier structure;
forming a second alignment mark;
positioning a second die over the first die, the second die comprising a peripheral edge comprising a side portion and a second non-linear alignment feature located along the side portion of the peripheral edge of the second die;
measuring positions of the second non-linear alignment feature on opposite sides of the second non-linear alignment feature using an optical detection system to determine a position of a centerline of the second non-linear alignment feature;
determining an offset distance between the centerline of the second non-linear alignment feature and a centerline of the second alignment mark; and
adjusting the position of the second die with respect to the first die until the offset distance is below a threshold value.

19. The method of claim 18, further comprising:
bonding the second die to the first die;
forming a second dielectric material layer over the first dielectric material layer and laterally surrounding the second die;
transferring the first die, the first dielectric material layer, the second die, and the second dielectric layer from the first carrier structure to a second carrier structure such that the second die is located between the first die and the second carrier structure; and
performing a dicing process through the first dielectric material layer, the second dielectric layer and the second carrier structure to form the bonded die structure.

20. The method of claim 17, wherein a second die is bonded to the first die using a dielectric-to-dielectric (D-D) and metal-to-metal (M-M) direct bonding technique.
